(19) United States
(12) Patent Application Publication
(10) Pub. No.: US 2019/0023960 A1
(43) Pub. Date: Jan. 24, 2019

(54) THERMALLY CONDUCTIVE BOARD

(71) Applicant: Polytronics Technology Corp., Hsinchu (TW)

(72) Inventors: KUO HSUN CHEN, Toufen City (TW); MENG CHUN KO, Taichung City (TW); YI AN SHA, XINDIAN CITY (TW)

(21) Appl. No.: 15/827,897

(22) Filed: Nov. 30, 2017

(30) Foreign Application Priority Data
Jul. 21, 2017 (TW) 106124509

(51) Int. Cl. C09K 5/14; C08L 63/00; B32B 15/092; B32B 15/20; H05K 1/02

(52) U.S. Cl. CPC C09K 5/14; H05K 1/09; B32B 15/092; B32B 15/20; H05K 1/0204; C08L 2205/025; C08L 2205/03; B32B 2264/102; B32B 2264/107; B32B 2307/206; B32B 2307/302; B32B 2457/08; H05K 2201/0242; H05K 2201/0209; C08L 63/00

(57) ABSTRACT

A thermally conductive board is a laminated structure comprising a metal substrate, a thermally conductive and electrically insulating layer and a metal layer. The thermally conductive and electrically insulating layer is disposed on the metal substrate, and the metal layer is disposed on the thermally conductive and electrically insulating layer. The thermally conductive and electrically insulating layer comprises polymer and non-spherical thermally conductive filler dispersed therein. The polymer comprises at least two straight-chain epoxy resins with different EEW. The product of a mean particle size and a BET surface area of the non-spherical thermally conductive filler is 7.5-15 μm·m²/g. The thermally conductive and electrically insulating layer has a Tg of 40-90° C. and a thermal conductivity of 1-6 W/m·K.

### BACKGROUND OF THE INVENTION

### (1) Field of the Invention

The present application relates to a thermally conductive board. More specifically, it relates to a metal-core thermally conductive board.

### (2) Description of the Related Art

Conventionally, a metal-core substrate, having a structure in which an insulating material layer is formed on a metal plate and a wiring pattern is formed on the insulating material layer, has been widely used as a heat dissipation substrate for mounting electronic components thereon. A wiring pattern is generally formed by laminating a copper foil on an insulating material layer, and ceramic chip elements, silicon semiconductors, terminals and the like are mounted on the wiring pattern with a solder.

As the insulating material layer, for example, a thermoplastic polyimide or a polyphenylene ether (PPE) to which an inorganic filler is added. However, since common resins such as thermoplastic polyimide or PPE have a low thermal conductivity, it may be difficult to use these resins for a heat dissipation substrate for electronic devices of recent years. Therefore, increasing thermal conductivity of an insulating material layer has been an issue for study, for example, the use of a crystalline resin or a highly heat-conductive filler as a means for increasing the thermal conductivity of a resin.

In automobile or other rigorous environments, high-temperature solarization or low-temperature chill is an ordeal for the endurance of the products. In such environments, a thermally conductive board on which the solder joint to the chips may crack due to thermal expansion and contraction would severely affect stability and reliability of the chips. To solve the problems and consider the practicability, the present application devises a thermally conductive board with high reliability.

### SUMMARY OF THE INVENTION

To solve the problems mentioned above, the present application proposed a metal-core thermally conductive board in which the composition of a thermally conductive and electrically insulating layer is improved to increase the stability in high-temperature and low-temperature environments and avoid solder joint cracking. Moreover, a metal layer of the thermally conductive board is improved to enhance peeling strength thereof.

In accordance with an embodiment of the present application, a thermally conductive board is a laminated structure comprising a metal substrate, a thermally conductive and electrically insulating layer and a metal layer. The thermally conductive and electrically insulating layer is disposed on the metal substrate, and the metal layer is disposed on the thermally conductive and electrically insulating layer. The thermally conductive and electrically insulating layer comprises polymer and non-spherical thermally conductive filler dispersed therein. The polymer comprises at least two straight-chain epoxy resins with different epoxy equivalent weights (EEW). The product of a mean particle size and a Brunauer-Emmett-Teller (BET) surface area of the non-spherical thermally conductive filler is 7.5-15 μm m²/g. The thermally conductive and electrically insulating layer has a glass transition temperature (Tg) of 40-90° C. and a thermal conductivity of 1-6 W/m K.

In an embodiment, the non-spherical thermally conductive filler comprises 35-65% by volume of the thermally conductive and electrically insulating layer.

In an embodiment, the non-spherical thermally conductive filler is selected from the group consisting of aluminum oxide, aluminum nitride, boron nitride and silicon carbide.

In an embodiment, the non-spherical thermally conductive filler comprises fragmental thermally conductive filler.

In an embodiment, the at least two straight-chain epoxy resins with different EEW have an average EEW of 400-2000 g/eq.

In an embodiment, the at least two straight-chain epoxy resins with different EEW have an average EEW of 800-1500 g/eq.

In an embodiment, one of the at least two straight-chain epoxy resins has an EEW of 100-400 g/eq, and another one of the at least two straight-chain epoxy resins has an EEW of 1500-4000 g/eq.

In an embodiment, at least one of the straight-chain epoxy resins has an EEW of 100-500 g/eq, and comprises more than 20% by weight of the polymer.

In an embodiment, the metal layer comprises a plating layer. The plating layer comprises zinc, chrome, nickel or combination thereof, and the plating layer is in direct contact with the thermally conductive and electrically insulating layer.

In an embodiment, the metal layer is a nickel-plated copper foil and the nickel-plated portion is in direct contact with the thermally conductive and electrically insulating layer.

In an embodiment, an attenuation of the peeling strength of the metal layer is less than 30% when the thermally conductive board is subjected to a high-pressure steaming process in a saturated vapor at 2 atmospheres (atm) and 121° C. for 96 hours.

In an embodiment, the thermally conductive and electrically insulating layer further comprises a latent curing agent.

In an embodiment, the latent curing agent is selected from the group consisting of amine adduct, hydrazide, dihydrazide, dicyandiamide (Dicy), adipic acid dihydrazide, and isophthalic dihydrazide.

In an embodiment, the amine adduct is a product of imidazole compound, tertiary amino group-containing compound or hydrazide compound reacted with epoxy compound or isocyanate compound.

In an embodiment, a viscosity of the thermally conductive and electrically insulating layer at 30° C. increases by less than 100% after 90 days.

The thermally conductive and electrically insulating layer of the thermally conductive board uses at least two straight-chain epoxy resins with different EEW and non-spherical thermally conductive filler. Because straight-chain epoxy resin is softer than side-chain epoxy resin, it can prevent solder joint cracking. The non-spherical thermally conductive filler has a larger surface area, the amount of the thermally conductive filler can be decreased by which the hardness of the material can be decreased to prevent solder joint cracking. It is noted that solder joint cracking is easily generated at a temperature higher than 90° C., and the peeling strength of the metal layer is attenuated after a high-pressure steaming process. The glass transition temperature of the polymer of the thermally conductive and electrically insulating layer is modified to 40-90° C., so as to effectively avoid cracks of solder joint between chips and the thermally conductive board due to thermal expansion and contraction in high and low temperature environments.

### BRIEF DESCRIPTION OF THE DRAWINGS

The present application will be described according to the appended drawings in which:

FIG. 1 shows a thermally conductive board in accordance with an embodiment of the present application; and

FIG. 2 and FIG. 3 show a manner for testing solder joint cracking of the present application.

### DETAILED DESCRIPTION OF THE INVENTION

The making and using of the presently preferred illustrative embodiments are discussed in detail below. It should be appreciated, however, that the present application provides many applicable inventive concepts that can be embodied in a wide variety of specific contexts. The specific illustrative embodiments discussed are merely illustrative of specific ways to make and use the invention, and do not limit the scope of the invention.

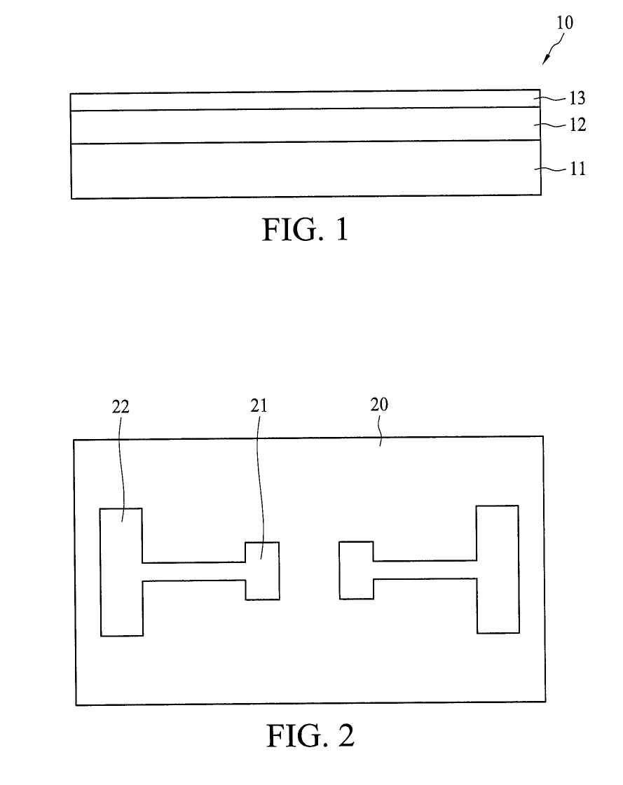

FIG. 1 illustrates a thermally conductive board 10 of the present application, comprising a metal substrate 11, a thermally conductive and electrically insulating layer 12, and a metal layer 13. The thermally conductive and electrically insulating layer 12 is disposed on the metal substrate 11, and the metal layer 13 is disposed on the thermally conductive and electrically insulating layer 12. The metal substrate 11, the thermally conductive and electrically insulating layer 12 and the metal layer 13 are laminated, e.g., a sandwiched structure in this embodiment. The thermally conductive and electrically insulating layer 12 comprises polymer and thermally conductive filler dispersed therein. More specifically, the thermally conductive filler is non-spherical, and the product of a mean particle size and a BET surface area of the non-spherical thermally conductive filler is 7.5-15 μm·m²/g. Because the non-spherical thermally conductive filler has a larger surface area, a desired or equivalent thermal conductivity can be achieved by using a smaller amount of the non-spherical thermally conductive filler. Accordingly, the hardness of the material of the thermally conductive and electrically insulating layer 12 can be decreased to prevent solder joint cracking.

Table 1 shows the polymer composition of the thermally conductive and electrically insulating layer 12 of the thermally conductive board 10 in accordance with exemplary embodiments E1-E5 and comparative examples C1-C4. The polymer comprises at least two straight-chain epoxy resins of different EEW. Because the straight-chain epoxy resin is softer than a side-chain epoxy resin, the straight-chain epoxy resin is beneficial to prevention of solder joint cracking. Nevertheless, the side-chain epoxy resin is advantageous to withstand high temperature, and therefore it can be added in the polymer by a small amount of less than 15% or 10% by volume. In E1-E5, the polymer of the thermally conductive and electrically insulating layer 12 is selected from the group consisting of Epoxy Resin 1, Epoxy Resin 2 and Epoxy Resin 3, e.g., a mixture of two or three epoxy resins. In this embodiment, Epoxy Resin 1 uses D.E.R.™ 331 of Dow Chemical Company with an EEW of 180 g/eq. Epoxy Resin 2 uses NPES-904 of Nan Ya Plastics Corporation with an EEW of 780 g/eq. Epoxy Resin 3 uses NPES-619C of Nan Ya Plastics Corporation with an EEW of 2700 g/eq. An average EEW of the polymer can be adjusted by mixing epoxy resins of different EEW as desired to obtain specific features, e.g., Tg, temperature endurance, or anti-dissolution. A larger average EEW has a lower Tg and a smaller crosslink density. The average EEW of E1-E5 is about 400-2000 g/eq, and preferably 800-1500 g/eq. For example, the average EEW of the polymer is 500, 600, 1000, 1200, 1500 or 1800 g/eq. The average EEW of C1 and C2 is 2316 g/eq, C3 purely uses Epoxy Resin 1 and has an average EEW of 180 g/eq, and C4 has an average EEW of 1248 g/eq. In an embodiment, the polymer comprises an epoxy resin with an EEW less than 1000 g/eq, e.g., 100-400 g/eq, and an epoxy resin with an EEW greater than 1500 g/eq, e.g., 1500-4000, for the ease of average EEW adjustment. In an embodiment, at least one of the straight-chain epoxy resins has an EEW of 100-500 g/eq and comprises more than 20% by weight of the polymer, so as to obtain better temperature endurance.

TABLE 1

| | Epoxy Resin 1 | Epoxy Resin 2 | Epoxy Resin 3 | Average |
|---|---|---|---|---|
| | EEW 180 g/eq | EEW 780 g/eq | EEW 2700 g/eq | EEW (g/eq) |
| E1 | 40 wt % | 10 wt % | 50 wt % | 1500 |
| E2 | 35 wt % | — | 65 wt % | 1818 |
| E3 | 50 wt % | 50 wt % | — | 480 |
| E4 | 40 wt % | 10 wt % | 50 wt % | 1500 |
| E5 | 50 wt % | 10 wt % | 40 wt % | 1248 |
| C1 | — | 20 wt % | 80 wt % | 2316 |
| C2 | — | 20 wt % | 80 wt % | 2316 |
| C3 | 100 wt % | — | — | 180 |
| C4 | 50 wt % | 10 wt % | 40 wt % | 1248 |

Table 2 shows the thermally conductive filler of the thermally conductive and electrically insulating layer 12 in accordance with the exemplary examples E1-E5 and the comparative examples C1-C4. The thermally conductive filler comprises non-spherical aluminum oxide, or a mixture of non-spherical aluminum oxide and non-spherical aluminum nitride. The non-spherical aluminum oxide uses AL-43M of Showa Denko K.K. which is a fragmental aluminum oxide with a mean particle size of 5.54 μm and a BET surface area of 1.68 m²/g. The non-spherical aluminum nitride uses a fragmental aluminum nitride which is a mixture from screening WJB and WM of Toyo Aluminum K.K and has a mean particle size of 5.65 μm and a BET surface area of 2.14 m²/g. Other non-spherical thermally conductive filler may comprise boron nitride and silicon carbide. In an embodiment, the non-spherical thermally conductive filler has a mean particle size of 1-30 μm and a BET surface area of 0.2-10 m²/g. For the same material, the mean particle size and the BET surface area are in inverse proportion. The product of a mean particle size and a BET surface area of the non-spherical thermally conductive filler is 7.5-15 μm·m²/g, e.g., 8, 10 or 12 μm·m²/g. Because the mean particle size has implication relating to size and distribution, the product is directly proportional to the entire surface area of the thermally conductive filler. The thermally conductive filler comprises 35-65%, e.g., 40%, 50% or 60%, by volume of the thermally conductive and electrically insulating layer 12. The thermally conductive filler of C1 and C4 uses DAM-05 of Denka Co., Ltd, a spherical aluminum oxide with a mean particle size of 5.4 μm and a BET surface area of 1.25 m²/g (a product of the mean particle size and the BET surface area is 6.75 μm·m²/g), and comprises 60-70% by volume of the thermally conductive and electrically insulating layer. C2 and C3 uses the aforesaid fragmental aluminum oxide and comprises 50% by volume of the thermally conductive and electrically insulating layer 12. The BET surface area of the fragmental thermally conductive filler is greater than that of the spherical thermally conductive filler by 20%. The thermally conductive and electrically insulating layer 12 further comprises the aforesaid epoxy resins and a curing agent and an accelerator. The curing agent is a latent curing agent, for example, AJICURE™ MY-24 of Ajinimoto Fine-Techno Co., Inc. The latent curing agent can extend the reservation period of semi-product before curing of the thermally conductive board.

TABLE 2

| | | | | Thermally |
|---|---|---|---|---|
| | | | | conductive |
| | Fragmental | Spherical | Fragmental | filler |
| | aluminum oxide | aluminum oxide | aluminum nitride | (vol %) |
| E1 | 100 wt % | — | — | 40 |
| E2 | 100 wt % | — | — | 50 |
| E3 | 100 wt % | — | — | 50 |
| E4 | 50 wt % | — | 50 wt % | 60 |
| E5 | 100 wt % | — | — | 62 |
| C1 | — | 100 wt % | — | 60 |
| C2 | 100 wt % | — | — | 50 |
| C3 | 100 wt % | — | — | 50 |
| C4 | — | 100 wt % | — | 67 |

Table 3 shows thermal conductivities and glass transition temperatures (Tg) of the thermally conductive and electrically insulating layer, and the test results of solder joint cracking and the attenuation (%) of peeling strength of the metal layer after high-pressure steaming 96 hours. The metal layer, e.g., a copper foil, is the metal layer 13 disposed on the thermally conductive and electrically insulating layer 12. The thermal conductivity of the thermally conductive and electrically insulating layer of E1-E5 is 1-6 W/m K, and Tg is 40-90° C., e.g., 50° C., 60° C., 70° C. or 80° C. All the thermally conductive boards 10 of E1-E5 pass the solder joint cracking test.

That is, the resistance measurements are normal. After the thermally conductive boards 10 of E1-E5 are subjected to high-pressure steaming testing in a saturated vapor at 2 atm. and 121° C. for 96 hours, the peeling strengths of the metal layers are decreased by less than 30%. To the contrary, the measured resistances are infinite in the solder joint cracking tests of C3 and C4. It indicates an electric open circuit and is viewed occurrence of solder joint cracking. The average EEW of C3 is less than 400 g/eq, or less than 200 g/eq, so that it has a higher Tg and is brittle to incur solder joint cracking. C4 uses spherical aluminum oxide with a large amount of 67% by volume for high thermal conductivity, inducing brittle property and solder joint cracking. The resistances of C1 and C2 are normal during solder joint cracking tests; however, the attenuations of the peeling strengths of the metal layers are over 50% and 40%, respectively, after high-pressure steaming for 96 hours. C1 and C2 have average EEW greater than 2000 g/eq, and therefore they have lower Tg and smaller crosslink density. As a result, the peeling strength of the metal layer is decreased by a wide margin during the high-pressure steaming tests. It appears that the C1-C4 cannot achieve no solder joint cracking and the attenuation of the peeling strengths of less than 30% simultaneously. E1-E5 can pass the solder joint cracking test, and the attenuation of peeling strength of metal layer is less than 30% during high-pressure steaming test.

TABLE 3

| | Thermal | | | Attenuation |
|---|---|---|---|---|
| | conductivity | | Solder joint | of peeling |
| | (W/m · K) | Tg (° C.) | cracking test | strength (%) |
| E1 | 1.5 | 50 | Normal resistance | 20 |
| E2 | 2 | 45 | Normal resistance | 25 |
| E3 | 2 | 85 | Normal resistance | 16 |
| E4 | 5.5 | 50 | Normal resistance | 24 |
| E5 | 5 | 62 | Normal resistance | 26 |
| C1 | 3.2 | 34 | Normal resistance | 51 |
| C2 | 1.5 | 34 | Normal resistance | 41 |
| C3 | 2 | 104 | Electric open | 11 |
| C4 | 4.7 | 62 | Electric open | 21 |

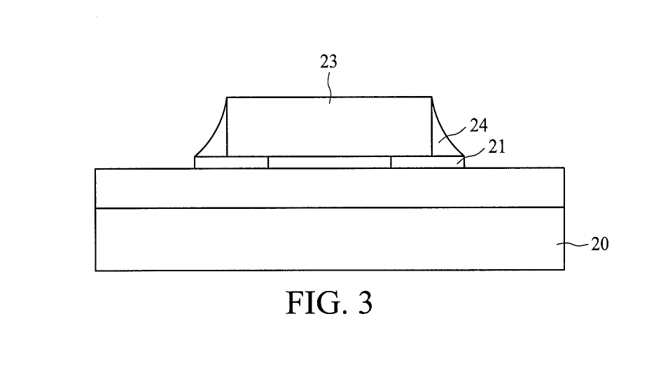

In FIG. 2, specimens 20 of 2.5 cm×1.5 cm are employed in the solder joint cracking tests. The specimen 20 has the same structure as the aforesaid thermally conductive board containing laminated metal substrate, thermally conductive and electrically insulating layer and metal layer. The metal layer is etched to form a pattern including bonding pads 21 and testing pads 22 with connections therebetween. Two ends of a resistance chip 23 is soldered onto the two bonding pads 21 by solder paste 24 as shown in FIG. 3 illustrating a side view of the testing structure. For simplification, the testing pads 22 and the related connecting circuits are not shown in FIG. 3.

When the resistance chip 23 is soldered onto the specimen 20, the two testing pads 22 are used for resistance measurement. In an embodiment, the resistance chip 23 uses PYU-RC0805 of YAGEO Corporation. The chip 23 has a size of 2.0 cm×1.2 cm and a resistance of 330±5% kΩ. The solder paste 24 uses TFL-204-171A of TAMURA Corporation. The specimen 20 associated with the resistance chip 23 is put into a temperature cycling chamber in which −40° C. is sustained for seven minutes and then the temperature rises to 125° C. and sustains for seven minutes as a cycle. Sequentially, the specimen 20 is cooled to −40° C. and repeats cycles. The resistance is measured after 2000 cycles, and it is viewed solder joint cracking in the solder paste 24 if the resistance is infinite.

In Table 4, the polymers of exemplary examples E6-E9 and comparative examples C5 and C6 comprise epoxy resin of an average EEW of 1248 and 100 parts by weight. Fragmental aluminum oxide of 50% by volume is employed as the non-spherical thermally conductive filler of the thermally conductive and electrically insulating layer. E6 and E7 use AJICURE™ MY-24 as a curing agent with 3.5 parts by weight. E8 uses AJICURE™ PN-50 as a curing agent with 3.5 parts by weight. MY-24 and PN-50 are latent curing agents of amine adduct. The latent curing agents of amine adduct of the present application may be a product of imidazole compound, tertiary amino group-containing compound or hydrazide compound reacted with epoxy compound or isocyanate compound. For example, AJICURE™ PN-23, AJICURE™ PN-40, AJICURE™ PN-50, AJICURE™ MY-24, AJICURE™ MY-H, Fujicure™ FXR-1030, AJICURE™ VDH, and AJICURE™ UDH. Other latent curing agents comprise hydrazide, dihydrazide, dicyandiamide (Dicy), adipic acid dihydrazide, and isophthalic dihydrazide. E9 uses AJICURE™ AH-154 as a curing agent with one part by weight. AH-154 is a Dicy latent curing agent. C5 uses JEFFAMINE® D-400 of Huntsman Corporation with 9.2 parts by weight as a curing agent. C6 uses methylhexahydrophthalic anhydride (MHHPA) of Lindau Chemicals, Inc. as a curing agent with 12 parts by weight. D-400 and MHHPA are not latent curing agents. The thermal conductivities of E6-E9 and C5-C6 are about 2 W/m·K. Because of different curing agents, Tg of E6-E9 are from 60° C. to 85° C., whereas Tg of C5 and C6 are 20° C. and 95° C., respectively. It appears that the latent curing agent of amine adduct induces lower Tg than that of Dicy latent curing agent and is more suitable for the present application. The metal layer of the thermally conductive board may be a copper foil or comprise a plated layer. The plated layer may comprise zinc, chrome, nickel or combination thereof, and the plated layer is in direct contact with the thermally conductive and electrically insulating layer. Each of E7, E8 and E9 uses a nickel-plated copper foil as a metal layer in which the nickel-plated portion is in direct contact with the thermally conductive and electrically insulating layer. In the solder joint cracking tests and high-pressure steaming tests, E6-E9 does not appear solder joint cracking, and the attenuation of the peeling strength of the metal layer after high-pressure steaming process is less than 30%. In particular, E7, E8 and E9 which use nickel-plated copper foils show less attenuation of the peeling strength of the metal layers, e.g., less than 15%, or 10%. Although C5 does not have solder joint cracking, the peeling strength of the metal layer after high-pressure steaming is decreased by 58%. C6 shows solder joint cracking. MY-24, PN-50 and AH-154 are latent curing agents, the pot lives of E6-E9 are more than 90 days or 120 days. However, C5 and C6 have pot lives of less than one day and only 24 days, respectively. The pot life is the time when the viscosity of the thermally conductive and electrically insulating layer increases by 100% at 30° C. It appears that the increase of the viscosity of the thermally conductive and electrically insulating layer of E6-E9 at 30° C. does not exceed 100% after 90 days or three months.

TABLE 4

| | | | | | | Attenu- |
|---|---|---|---|---|---|---|
| | | | | | | ation of |
| | | | | | | peeling |
| | Curing | Pot life | | Tg | Solder joint | strength |
| | agent | (days) | Metal layer | (° C.) | cracking test | (%) |
| E6 | MY-24 | >90 | Copper foil | 62 | Normal | 26 |
| | | | | | resistance | |
| E7 | MY-24 | >90 | Nickel-plated | 62 | Normal | 6 |
| | | | copper foil | | resistance | |
| E8 | PN-50 | >120 | Nickel-plated | 78 | Normal | 5 |
| | | | copper foil | | resistance | |
| E9 | AH-154 | >120 | Nickel-plated | 85 | Normal | 3 |
| | | | copper foil | | resistance | |
| C5 | D-400 | <1 | Copper foil | 20 | Normal | 58 |
| | | | | | resistance | |
| C6 | MHHPA | 24 | Copper foil | 95 | Electric open | 28 |

The polymer of the thermally conductive and electrically insulating layer comprises at least two epoxy resins with different EEW and a latent curing agent to obtain a low Tg, e.g., 40-90° C., so as to effectively avoid solder joint cracking between chips and the thermally conductive board due to thermal expansion and contraction in high and low temperature environments. The straight-chain epoxy resin is softer than side-chain epoxy resin, and therefore it can prevent solder joint cracking. In particular, the product of a mean particle size and a BET surface area of the non-spherical thermally conductive filler of the present application is 7.5-15 μm·m²/g. Because the non-spherical thermally conductive filler provides a larger entire surface area, a smaller amount of the thermally conductive filler is needed. As a result, a lower hardness can be obtained to avoid solder joint cracking.

The above-described embodiments of the present invention are intended to be illustrative only. Numerous alternative embodiments may be devised by persons skilled in the art without departing from the scope of the following claims.

What is claimed is:

1. A thermally conductive board, comprising:
a metal substrate;
a thermally conductive and electrically insulating layer disposed on the metal substrate, and the thermally conductive and electrically insulating layer comprising polymer and non-spherical thermally conductive filler dispersed in the polymer, the polymer comprises at least two straight-chain epoxy resins with different EEW, the product of a mean particle size and a BET surface area of the non-spherical thermally conductive filler being 7.5-15 μm·m²/g, the thermally conductive and electrically insulating layer having a glass transition temperature of 40-90° C. and a thermal conductivity of 1-6 W/m·K; and
a metal layer disposed on the thermally conductive and electrically insulating layer;
wherein the metal substrate, the thermally conductive and electrically insulating layer and the metal layer are laminated.

2. The thermally conductive board of claim 1, wherein the non-spherical thermally conductive filler comprises 35-65% by volume of the thermally conductive and electrically insulating layer.

3. The thermally conductive board of claim 1, wherein the non-spherical thermally conductive filler is selected from the group consisting of aluminum oxide, aluminum nitride, boron nitride and silicon carbide.

4. The thermally conductive board of claim 1, wherein the non-spherical thermally conductive filler comprises fragmental thermally conductive filler.

5. The thermally conductive board of claim 1, wherein the at least two straight-chain epoxy resins with different EEW have an average EEW of 400-2000 g/eq.

6. The thermally conductive board of claim 1, wherein the at least two straight-chain epoxy resins with different EEW have an average EEW of 800-1500 g/eq.

7. The thermally conductive board of claim 1, wherein one of the at least two straight-chain epoxy resins has an EEW of 100-400 g/eq, and another one of the at least two straight-chain epoxy resins has an EEW of 1500-4000 g/eq.

8. The thermally conductive board of claim 1, wherein at least one of the straight-chain epoxy resins has an EEW of 100-500 g/eq, and comprises more than 20% by weight of the polymer.

9. The thermally conductive board of claim 1, wherein the metal layer comprises a plating layer of zinc, chrome, nickel or combination thereof, and the plating layer is in direct contact with the thermally conductive and electrically insulating layer.

10. The thermally conductive board of claim 1, wherein the metal layer is a nickel-plated copper foil, and the nickel-plated portion is in direct contact with the thermally conductive and electrically insulating layer.

11. The thermally conductive board of claim 10, wherein an attenuation of a peeling strength of the metal layer is less than 30% after the thermally conductive board is subjected to a high-pressure steaming process in a saturated vapor at 2 atmospheres and 121° C. for 96 hours.

12. The thermally conductive board of claim 1, wherein the thermally conductive and electrically insulating layer further comprises a latent curing agent.

13. The thermally conductive board of claim 12, wherein the latent curing agent is selected from the group consisting of amine adduct, hydrazide, dihydrazide, dicyandiamide, adipic acid dihydrazide, and isophthalic dihydrazide.

14. The thermally conductive board of claim 13, wherein the amine adduct is a product of imidazole compound, tertiary amino group-containing compound or hydrazide compound reacted with epoxy compound or isocyanate compound.

15. The thermally conductive board of claim 12, wherein a viscosity of the thermally conductive and electrically insulating layer at 30° C. increases by less than 100% after 90 days.
